(19) United States
(12) Patent Application Publication
(10) Pub. No.: US 2025/0364698 A1
(43) Pub. Date: Nov. 27, 2025

(54) Flexible Substrate and Battery Connection Structure

(71) Applicant: Yazaki Corporation, Tokyo (JP)

(72) Inventor: Makoto Ogawa, Makinohara-shi (JP)

(21) Appl. No.: 19/200,155

(22) Filed: May 6, 2025

(30) Foreign Application Priority Data
May 27, 2024 (JP) 2024-085474

(51) Int. Cl. H01M 50/519; H05K 1/02

(52) U.S. Cl. CPC H01M 50/519; H05K 1/0277; H05K 2201/09027

(57) ABSTRACT

A flexible substrate includes a plate-shaped substrate body arranged perpendicular to a vertical direction, and a connection portion elongating and extending. The connection portion includes an extraction portion, a bent portion, a first extending portion that extends from the bent portion to a positive side in a x direction, a folded portion, a second extending portion that extends in parallel and opposite to the first extending portion, and a fixing portion. The first extending portion is inclined downward to the positive side in the x direction. The second extending portion is inclined downward to the negative side in the x direction. The fixing portion can be made sufficiently lower than the substrate body even when inclination angles of the first extending portion and the second extending portion are made small.

### CROSS-REFERENCE TO RELATED APPLICATIONS

This application is based on and claims priority under 35 USC 119 from Japanese Patent Application No. 2024-085474 filed on May 27, 2024, the contents of which are incorporated herein by reference.

### TECHNICAL FIELD

The present disclosure relates to a structure of a flexible substrate used for a battery cell or the like, and a battery connection structure using the flexible substrate.

### BACKGROUND ART

In a battery cell used in an automobile or the like, an output of a large current is extracted on a battery basis from an assembly including plural batteries, and these outputs are connected in series, for example. For this reason, a substrate including a terminal connected to an electrode of each battery is attached to such a battery cell (battery assembly). At this time, a position of the terminal on the battery side changes due to heat generation of the battery during use, thermal expansion caused by environmental temperature, expansion of the battery itself, and the like. On the other hand, since a large current is output from each battery, the substrate and each battery are required to be reliably connected at low resistance.

To cope with such a positional change, a flexible substrate (flexible printed circuit board) as described in, for example, Patent Literature 1, is used as the substrate. In the flexible substrate, a wiring pattern through which a current flows is formed on a substrate formed of a thin flexible resin material. A connection portion on which the wiring pattern is provided extends from a substrate body and is fixed to an electrode on the battery side.

FIG. 7A is a plan view illustrating a mode when a flexible substrate 300 is attached to a battery 50, and FIG. 7B is a cross-sectional view thereof in an A-A direction. Here, the flexible substrate 300 is connected to an electrode (positive-side electrode or negative-side electrode) 55 in the battery 50. In the flexible substrate 300, a plate-shaped substrate body 310 and a connection portion 320 elongated from the substrate body 310 extend and are connected to the electrode 55. A wiring pattern is appropriately formed on the substrate body 310 and the connection portion 320, and description thereof is omitted. The substrate body 310 is configured such that a current is extracted to the outside.

As illustrated in FIG. 7A, the connection portion 320, one end of which is connected to the substrate body 310, has a bent shape in a horizontal direction (in-plane direction of the flexible substrate 300). A rectangular plate-shaped connection terminal 40, which is made of metal, is connected to a fixing portion 330 provided on the other end, and the connection terminal 40 is connected via a metal bonding layer 57 on the electrode 55. With this structure, the connection with the electrode 55 on the battery 50 side is maintained even when a position of the battery 50 (electrode 55) changes.

### CITATION LIST

### Patent Literature

Patent Literature 1: JP2022-97917A

### SUMMARY OF INVENTION

With the above structure, the connection to the electrode 55 can be maintained stable even when the position of the battery 50 (electrode 55) changes. However, the position change of the battery 50 may occur in both a left-right direction and an upper-lower direction in FIG. 7A, which may occur at the same time.

FIG. 8 is a plan view corresponding to FIG. 7A in this case. In this case, although the connection between the connection terminal 300 and the electrode 55 is maintained stable, the connection portion 300 may be deformed, and the connection portion 320 and the substrate body 310 may interfere as in a region B, or different parts of the bent connection portion 320 may interfere with each other as in a region C. At this time, even in a state (FIGS. 7A and 7B) before deformation particularly as in the region C, interference may particularly occur due to manufacturing tolerances in a part where an interval is small. Accordingly, the connection portion 320 and the substrate body 310 may be damaged, and a problem may occur in extracting a current from the battery 50.

The present disclosure is made in view of the above circumstances and an object thereof is to solve the above problems.

A flexible substrate of the present disclosure is a thin plate-shaped substrate made of a flexible material and is formed with a wiring pattern that is a path of a current from a battery. The flexible substrate includes a substrate body having a surface perpendicular to a vertical direction, and a connection portion branching and extending from an extraction portion of the substrate body in a plan view, a distal end portion of the connection portion serving as a fixing portion to be fixed to an electrode of the battery. The connection portion is bent in a plurality of positions in a plan view from the extraction portion to the fixing portion to change an extending direction. The connection portion is inclined such that a distance from the substrate body along the vertical direction increases as the connection portion extends from the extraction portion along the extending direction, and thereby the fixing portion and the substrate body are not provided at the same height in the vertical direction. In other words, the connection portion is inclined in the vertical direction so as to be spaced away from the substrate body so that the fixing portion and the substrate body are provided at different heights in the vertical direction.

Further, the connection portion may include a first extending portion and a second extending portion that extend in opposite directions along a second direction perpendicular to a first direction that is a direction from the substrate body toward the battery in a plan view.

Further, in a battery connection structure using the flexible substrate in the present disclosure, the fixing portion and the electrode are connected via a plate-shaped connection terminal.

The substrate body may be disposed above the electrode, and the connection terminal may be joined to a lower side of the fixing portion.

Since the present disclosure is configured as described above, it is possible to obtain a flexible substrate that can stably extract an output from a connected electrode even when a position of the electrode changes.

### BRIEF DESCRIPTION OF DRAWINGS

FIG. 1 is a plan view illustrating a first mode (electrode connection structure) when a flexible substrate according to an embodiment is used;

FIGS. 2A to 2C are cross-sectional views illustrating the first mode (electrode connection structure) when the flexible substrate according to the present embodiment is used;

FIG. 3 is a plan view illustrating a second mode (electrode connection structure) when the flexible substrate according to the present embodiment is used;

FIGS. 4A to 4C are cross-sectional views illustrating the second mode (electrode connection structure) when the flexible substrate according to the present embodiment is used;

FIG. 5 is a plan view illustrating a mode when a first modification of the flexible substrate according to the present embodiment is used;

FIG. 6 is a plan view illustrating a mode when a second modification of the flexible substrate according to the present embodiment is used;

FIGS. 7A and 7B are plan views illustrating a mode when a flexible substrate in the related art is used; and

FIG. 8 is a cross-sectional view illustrating the mode when the flexible substrate in the related art is used.

### DESCRIPTION OF EMBODIMENTS

A flexible substrate according to an embodiment of the present disclosure will be described. The flexible substrate is also provided with a connection portion used for electrical connection with an electrode of a battery cell (battery), and the connection therebetween is maintained even when a position of the battery (electrode) changes due to flexibility of the flexible substrate. Further, in the flexible substrate, the connection portion connected to the battery and the substrate body, or different portions of the connection portion, are less likely to interfere with each other even when the battery (electrode) moves.

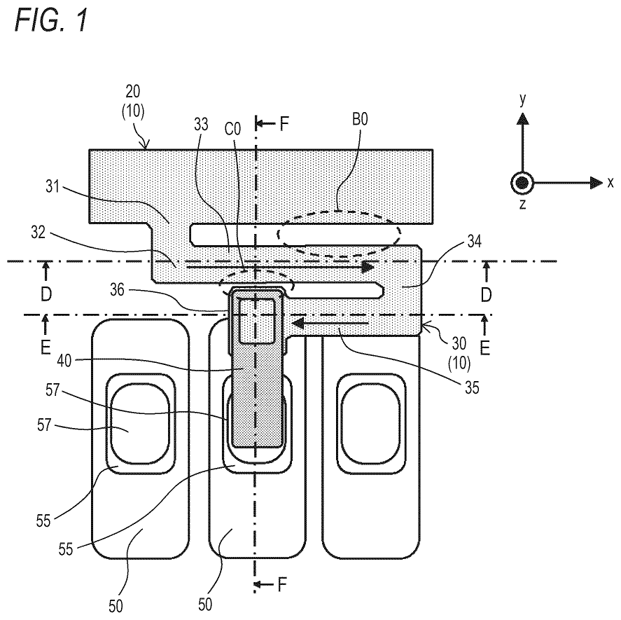

FIG. 1 is a plan view illustrating a mode (battery connection structure) when a flexible substrate 10 is attached to a battery 50. Here, x, y, and z directions are defined as illustrated here, the y direction (first direction) is a direction connecting a substrate body 20 and the battery 50 in a plan view, the x direction (second direction) is a direction in a horizontal plane which is perpendicular to the y direction, and the z direction is a vertical direction.

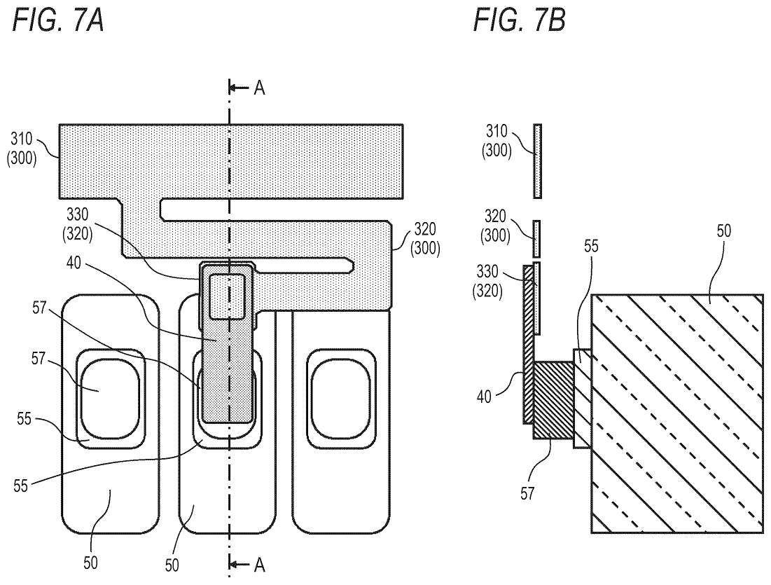

Similar to a configuration in FIGS. 7A and 7B, here, the flexible substrate 10 is also provided with a plate-shaped substrate body 20 perpendicular to the vertical direction (z direction) and a connection portion 30 elongated from the substrate body 20. The flexible substrate 10 is further provided with a metal connection terminal 40 for connecting a metal bonding layer 57 on an electrode 55 and the connection portion 30. The plan view illustrated in FIG. 1 is substantially the same as a plan view illustrated in FIG. 7A. Here, the connection portion 30 includes an extraction portion 31 that is a part extracted from the substrate body 20 to a negative side in the y direction, a bent portion 32 that changes an extending direction from the extraction portion 31 by 90° (into the x direction), a first extending portion 33 that extends from the bent portion 32 to a positive side in the x direction, a folded portion 34 that is provided on the positive side in the x direction of the first extending portion 33 and changes the extending direction by 180°, a second extending portion 35 that extends in parallel and opposite to the first extending portion 33, and a fixing portion 36 that is provided at a distal end of the second extending portion 35 and to which the connection terminal 40 is connected. The plan view illustrated in FIG. 1 is substantially the same as the plan view illustrated in FIG. 7A.

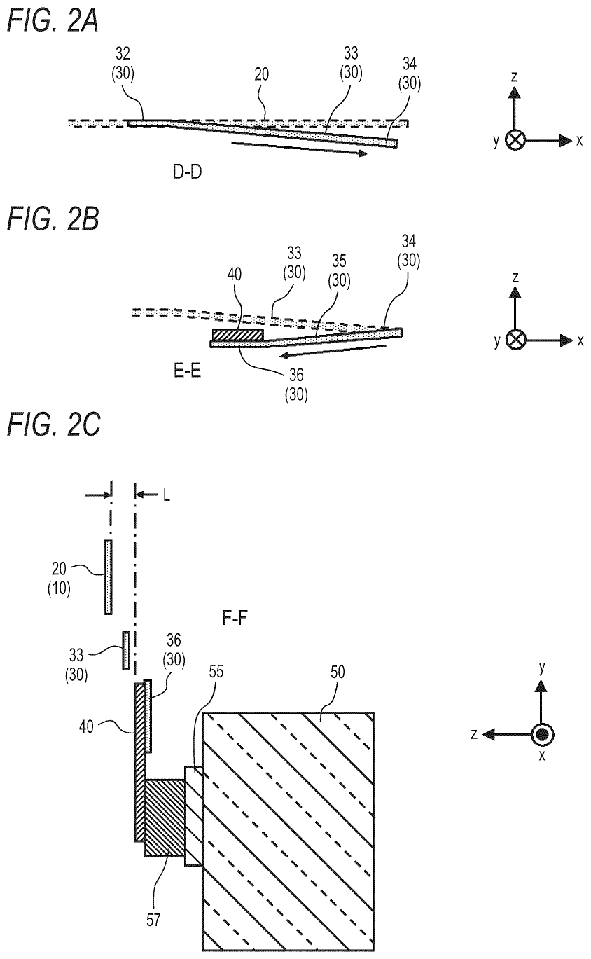

On the other hand, FIG. 2A is a cross-sectional view taken along a D-D direction in FIG. 1, FIG. 2B is a cross-sectional view taken along an E-E direction in FIG. 1, and FIG. 2C is a cross-sectional view taken along an F-F direction in FIG. 1. In particular, FIG. 2C corresponds to FIG. 7B. As illustrated in FIG. 2A, the first extending portion 33 is inclined downward (to a negative side in the z direction) to the positive side in the x direction. As illustrated in FIG. 2B, the second extending portion 35 is inclined downward (to the negative side in the z direction) to a negative side in the x direction. In FIG. 1, such inclined parts are indicated by arrows whose tip ends are on a lower side. For this reason, as illustrated in FIG. 2C, the fixing portion 36 is located below (negative side in the z direction) the substrate body 20, and in this case, a distance between a lower face of the substrate body 20 and an upper face of the connection terminal 40 in the z direction is L.

In particular, by providing the bent portion 32 and the folded portion 34 in the connection portion 30, an effective length from the extraction portion 31 to the fixing portion 36 (connection terminal 40) can be made large, and the fixing portion 36 can be made sufficiently lower than the substrate body 20 even when inclination angles of the first extending portion 33 and the second extending portion 35 in FIGS. 2A and 2B are made small.

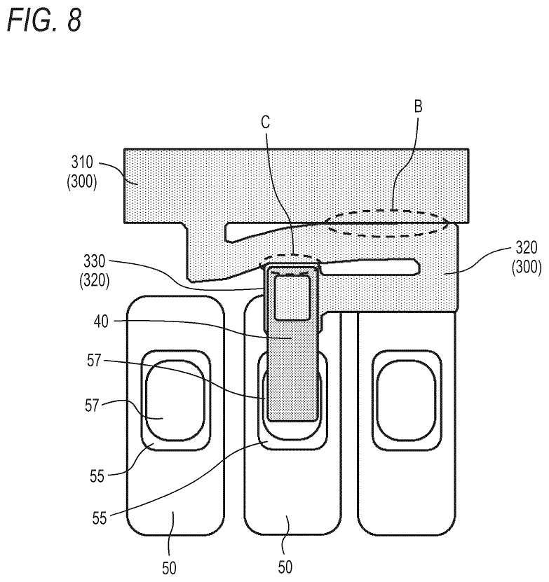

In FIG. 1, a part where the connection portion 30 (first extending portion 33) and the substrate body 20 face each other corresponding to a region B in FIG. 8 is illustrated as a region B0, and a part where the first extending portion 33 and the fixing portion 36 face each other corresponding to a region C is illustrated as a region C0. With the above configuration, since the first extending portion 33 is located in a position lower than the substrate body 20 in the region B0, and the fixing portion 36 is located in a position lower than the first extending portion 33 in the region C0, interference is prevented in the regions B0 and C0 even when the same deformation as in FIG. 8 occurs in the connection portion 30 (flexible substrate 10).

In the configuration of FIGS. 1 and 2A to 2C, it is apparent that even when the electrode 55 (battery 50) slightly moves along the z direction, deformation of the connection portion 30 can follow the slight movement. For this reason, even when a position of the connected electrode 55 changes, an output from the electrode can be stably extracted.

FIG. 1 illustrates a configuration in which one flexible substrate 10 is connected to a single battery 50, and actually, another flexible substrate is also connected to another battery 50 adjacent to this battery 50 in the same way. In this case, substrate bodies of the flexible substrates may be common or separate. In a case of separate substrate bodies, heights of the substrate bodies may be different on a battery basis, and the inclination angles in FIGS. 2A to 2C may be changed accordingly.

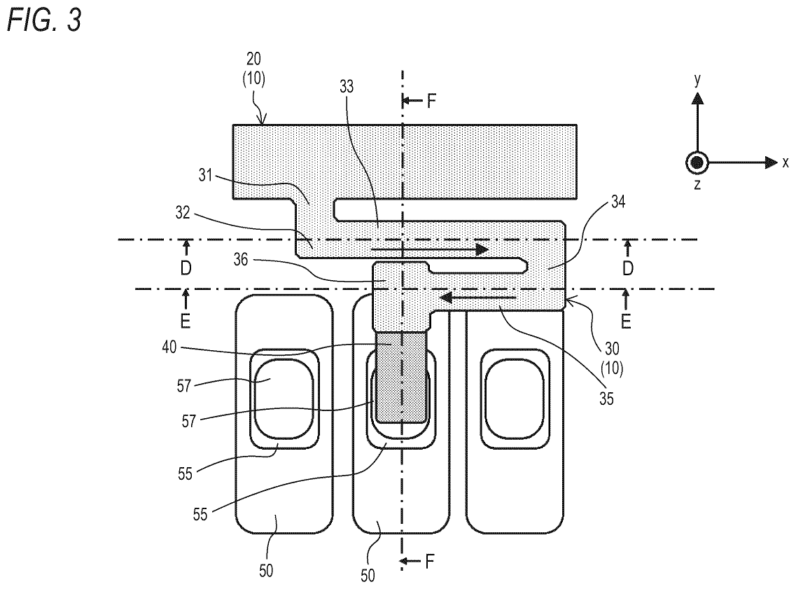

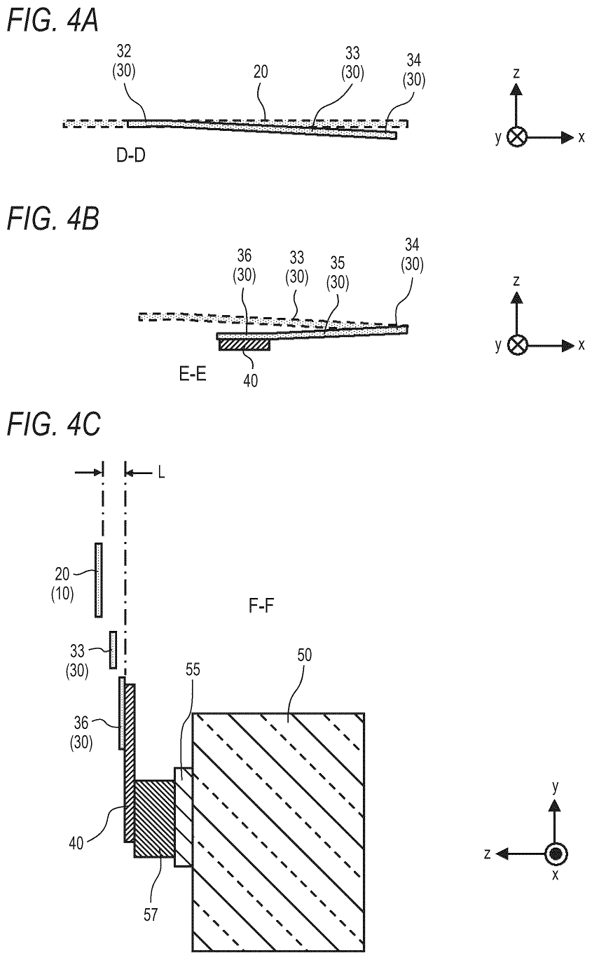

FIGS. 3 and 4A to 4C illustrate a structure (electrode connection structure) in which the flexible substrate 10 is used in a mode different from that of FIGS. 1 and 2A to 2C, and correspond to FIGS. 1 and 2A to 2C. In the example of FIGS. 1 and 2A to 2C, the connection terminal 40 is connected to an upper side (positive side in the z direction) of the fixing portion 36, and in this configuration, the connection terminal 40 is connected to a lower side of the fixing portion 36. Here, in an attached state, the connection terminal 40 is maintained horizontal as illustrated in FIG. 4C.

When the distance between the substrate body 20 and the connection terminal 40 in the z direction in FIG. 2C is L and the distance remains the same in the configuration of FIGS. 3 and 4A to 4C as illustrated in FIG. 4C, a height of the fixing portion 36 in this case can be increased by a thickness of the connection terminal 40. For this reason, the inclination angles of the first extending portion 33 and the second extending portion 35 in FIGS. 4A and 4B can be made gentler than those in FIGS. 2A and 2B.

A resin material that is a body of the flexible substrate 10 is made sufficiently thinner than the connection terminal 40 or the like as illustrated in FIGS. 2A to 2C and 4A to 4C. Accordingly, it is apparent that interference between the connection portion 30 and the substrate body 20 and interference between the first extending portion 33 and the fixing portion 36 are also prevented by this configuration. On the other hand, when this configuration is used, the entire connection portion 30 can be shortened by an amount the inclinations are made gentler, and overall strength can also be increased.

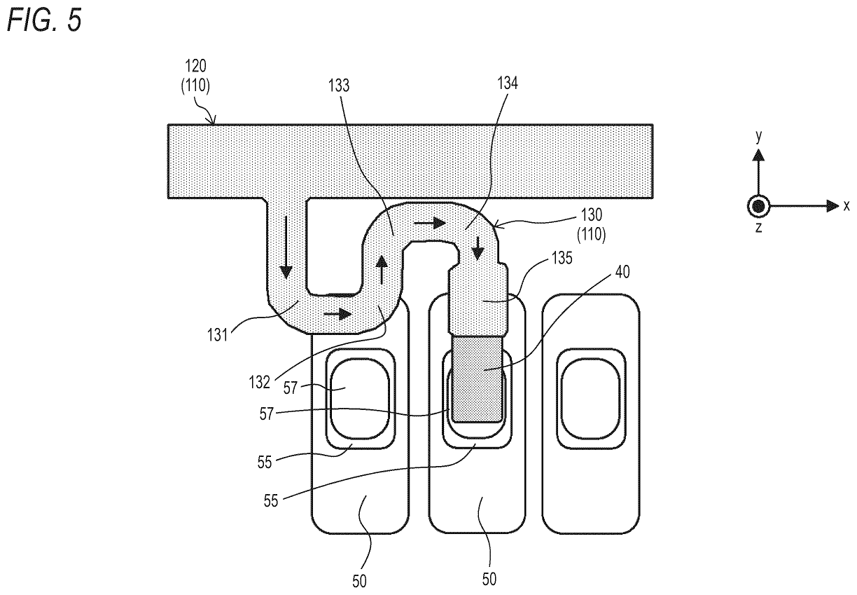

In the flexible substrate 10, in particular, a planar shape of the connection portion can be appropriately changed. In a flexible substrate 110 (first modification) illustrated in FIG. 5, a connection portion 130 bent as illustrated in the drawing is formed on a substrate body 120. In the connection portion 30, the extending direction is changed in two portions (bent portion 32, folded portion 34), whereas in the connection portion 130, bent portions 131, 132, 133, and 134 each changing the extending direction by 90° are provided, and a fixing portion 135 is provided at a distal end. By providing multiple bent portions in this manner and inclining the connection portion 130 toward the distal end among the bent portions as indicated by arrows in FIG. 5, similar to FIGS. 2A and 2B, an output can be stably extracted from the electrode 55 in the same way. Also in this case, the connection terminal 40 is connected to a lower side of the fixing portion 135, which is similar to the configuration of FIGS. 3 and 4A to 4C.

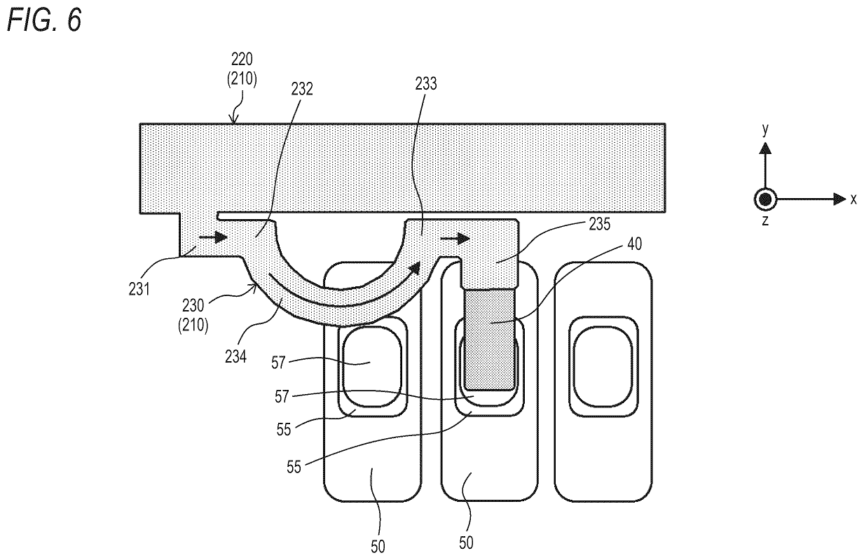

In a flexible substrate 210 (second modification) illustrated in FIG. 6, a connection portion 230 having a shape illustrated in the drawing is formed on a substrate body 220. In the connection portion 230, bent portions 231, 232, and 233 each changing the extending direction by 90° are provided, and a curved portion 234 having an arc shape is provided between the bent portion 232 and the bent portion 233. In this way, the same effect can be obtained by combining the bent portions and the curved portion having a curved shape and inclining these portions toward a distal end (fixing portion 235) as indicated by arrows in FIG. 6. Also in this case, the connection terminal 40 is connected to a lower side of the fixing portion 235, which is similar to the configuration of FIGS. 3 and 4A to 4C.

In this way, by providing a plurality of bent portions and folded portions and inclining the connection portion toward a distal end among the bent portions and folded portions, similar to FIGS. 2A and 2B, an output can be stably extracted from the electrode 55 in the same way.

A fixing portion is provided below (negative side in the z direction) a substrate body in the above examples. Alternatively, the fixing portion may be provided above the substrate body according to a positional relationship between the substrate body (flexible substrate) and a battery. In this case, inclinations of the connection portion (first extending portion 33, second extending portion 35) illustrated in FIGS. 2A and 2B may be reversed. That is, regions of the connection portion may be inclined relative to the substrate body in the vertical direction toward where the fixing portion at a distal end is provided.

A configuration of the substrate body is appropriately set according to a method for extracting a current from the battery, and the connection portion is appropriately configured such that a path of the current at this time is ensured from the fixing portion.

The present disclosure has been described above based on the embodiment. The embodiment is merely an example, and it will be understood by those skilled in the art that various modifications are possible in combinations of components in the embodiment, and that the modifications are also within the scope of the present disclosure.

What is claimed is:

1. A flexible substrate that is a thin plate-shaped substrate made of a flexible material and is formed with a wiring pattern that is a path of a current from a battery, the flexible substrate comprising:
a substrate body having a surface perpendicular to a vertical direction; and
a connection portion branching and extending from an extraction portion of the substrate body in a plan view, a distal end portion of the connection portion serving as a fixing portion to be fixed to an electrode of the battery, wherein
the connection portion is bent in a plurality of positions in a plan view from the extraction portion to the fixing portion to change an extending direction,
the connection portion is inclined such that a distance from the substrate body along the vertical direction increases as the connection portion extends from the extraction portion to the fixing portion along the extending direction, and
the fixing portion and the substrate body are not provided at the same height in the vertical direction.

2. The flexible substrate according to claim 1, wherein
the connection portion includes a first extending portion and a second extending portion that extend in opposite directions along a second direction perpendicular to a first direction that is a direction from the substrate body toward the battery in a plan view.

3. A battery connection structure using the flexible substrate according to claim 1, wherein
the fixing portion and the electrode are connected via a plate-shaped connection terminal.

4. The battery connection structure according to claim 3, wherein
the substrate body is disposed above the electrode, and
the connection terminal is joined to a lower side of the fixing portion.
